(19) United States
(12) Patent Application Publication
(10) Pub. No.: US 2025/0029849 A1
(43) Pub. Date: Jan. 23, 2025

(54) SHAPED FACEPLATE FOR EXTREME EDGE FILM UNIFORMITY

(71) Applicant: Applied Materials, Inc., Santa Clara, CA (US)

(72) Inventors: Anish Janakiraman, Bangalore (IN); Mayur Govind Kulkarni, Bangalore (IN); Deenesh Padhi, Sunnyvale, CA (US)

(73) Assignee: Applied Materials, Inc., Santa Clara, CA (US)

(21) Appl. No.: 18/223,184

(22) Filed: Jul. 18, 2023

(51) Int. Cl. H01L 21/67; H01L 21/687

(52) U.S. Cl. CPC H01L 21/6719; H01L 21/67103; H01L 21/67207; H01L 21/68785

(57) ABSTRACT

Exemplary semiconductor processing chambers may include a chamber body. The chambers may include a substrate support within the chamber body. The substrate support may define a substrate support surface. The chambers may include a faceplate supported atop the chamber body. The substrate support and a bottom surface of the faceplate may at least partially define a processing region. The bottom surface of the faceplate may define an annular protrusion that is directly above at least a portion of a radially outer 10% of the substrate support surface and an annular groove that is positioned radially outward of the annular protrusion. At least a portion of the annular groove may extend radially outward beyond the substrate support surface. The faceplate may define apertures through the faceplate. A first subset of the apertures may extend through the annular protrusion and a second subset of the apertures may extend through the annular groove.

### TECHNICAL FIELD

The present technology relates to components and apparatuses for semiconductor manufacturing. More specifically, the present technology relates to processing chamber distribution components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

Exemplary semiconductor processing chambers may include a chamber body. The chambers may include a substrate support disposed within the chamber body. The substrate support may define a substrate support surface. The chambers may include a faceplate positioned supported atop the chamber body. The substrate support and a bottom surface of the faceplate may at least partially define a processing region within the semiconductor processing chamber. The bottom surface of the faceplate may define an annular protrusion that is disposed directly above at least a portion of a radially outer 10% of the substrate support surface and an annular groove that is positioned radially outward of the annular protrusion. At least a portion of the annular groove may extend radially outward beyond the substrate support surface. The faceplate may define a plurality of apertures through the faceplate. A first subset of the plurality of apertures may extend through the annular protrusion and a second subset of the plurality of apertures may extend through the annular groove.

In some embodiments, the substrate support may include a heater pocket that protrudes upward from an upper surface of the substrate support. The annular protrusion may be disposed radially inward of a peripheral edge of the heater pocket. An outer edge of the annular protrusion may be at a same radial position as an inner edge of the annular groove. A vertical distance between a peak of the annular protrusion and a valley of the annular groove may be between about 0.05 inches and 0.3 inches. Transition areas between a main surface of the bottom surface of the faceplate one or both of the annular protrusion and the annular groove comprise rounded corners. A width of one or both of the annular protrusion and the annular groove may be between about 0.05 inches and 0.5 inches. The annular protrusion may protrude from a main surface of the bottom surface of the faceplate by a distance of between about 0.005 inches and 0.2 inches. The annular groove may be recessed relative to a main surface of the bottom surface of the faceplate by a distance of between about 0.001 inches and 0.05 inches. Walls defining the annular groove may extend at an angle of between about 10 degrees and 45 degrees relative to a main surface of the bottom surface of the faceplate.

Some embodiments of the present technology may encompass semiconductor processing faceplates. The faceplates may include a body defining a top surface and a bottom surface of the faceplate. The bottom surface of the faceplate may define an annular protrusion and an annular groove that is positioned radially outward of the annular protrusion. An outer edge of the annular protrusion may be within 5 mm of an inner edge of the annular groove. The faceplate may define a plurality of apertures through the faceplate. A first subset of the plurality of apertures may extend through the annular protrusion and a second subset of the plurality of apertures may extend through the annular groove. An outermost aperture of the plurality of apertures may extend through the annular groove.

In some embodiments, a transition area between the annular protrusion and the annular groove may include rounded corners. Each of the plurality of apertures may include an upper cylindrical portion and a lower cylindrical portion. The lower cylindrical portion may have a smaller diameter than the upper cylindrical portion. The lower cylindrical portion of each of the plurality of apertures may have a same length and diameter. A flow conductance through substantially all of the plurality of apertures may be substantially equal. A protrusion distance of the annular protrusion may vary across a width of the annular protrusion. A distance from a trough of the annular groove and a main surface of the bottom surface of the faceplate may be greater than or equal to a distance from a peak of the annular protrusion and the main surface. The annular protrusion may not be parallel with a main surface of the bottom surface of the faceplate.

Some embodiments of the present technology may encompass methods of processing a substrate. The methods may include flowing a precursor into a processing chamber. The processing chamber may include a faceplate and a substrate support on which a substrate is disposed. A processing region of the processing chamber may be at least partially defined between the faceplate and the substrate support. A bottom surface of the faceplate may define an annular protrusion that is disposed directly above at least a portion of a radially outer 10% of the substrate and an annular groove that is positioned radially outward of the annular protrusion. At least a portion of the annular groove may extend radially outward beyond the substrate. The faceplate may define a plurality of apertures through the faceplate. A first subset of the plurality of apertures may extend through the annular protrusion and a second subset of the plurality of apertures may extend through the annular groove. The methods may include generating a plasma of the precursor within a processing region of the processing chamber. The methods may include depositing a material on the substrate.

In some embodiments, the annular protrusion and the annular groove may contact one another. A vertical distance between a peak of the annular protrusion and a valley of the annular groove may be between about 0.05 inches and 0.3 inches.

Such technology may provide benefits over conventional systems and techniques. For example, embodiments of the present technology may allow controlled deposition at an edge region of a substrate. Additionally, the components may maintain edge region plasma generation to reduce effects on plasma density and distribution. Embodiments may enable deposition rates to be controlled solely using adjustments to the shape of an electrode (e.g., a faceplate or showerhead) in some embodiments. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2A shows a schematic cross-sectional view of an exemplary processing chamber according to some embodiments of the present technology.

FIG. 2B shows a partial schematic cross-sectional view of a faceplate of FIG. 2A.

FIG. 3 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity. Many chambers include a characteristic process signature, which may produce residual non-uniformity across a substrate. Temperature differences, flow pattern uniformity, and other aspects of processing may impact the films on the substrate, creating film uniformity differences across the substrate for materials produced or removed. For example, turbulent deposition gas flow and/or misalignment of apertures of a blocker plate and faceplate of a gas box may lead to non-uniform flow of deposition gases. In particular, many processes suffer from non-uniformity issues, especially toward the edge region of the substrate. For example, while deposition at inner region (e.g., an inner 80%) of the substrate may be tuned by hardware and process parameters, the edge region of the substrate may be insensitive to such tuning elements. This may be due, at least in part on the geometry of the substrate support. For example, in many chambers the substrate support may include a heater pocket in which the substrate is seated. Just radially outward of the substrate are walls forming the peripheral edge of the heater pocket. The presence of these walls, and the slight gap between a peripheral edge of the substrate and the walls may create discontinuities that generate unique flow and temperature characteristics that may impact deposition rates at areas of the substrate proximate this region (i.e., the edge region of the substrate). Oftentimes, the edge region may exhibit a lower deposition rate than the inner region, except at the very edge (e.g., outer 2%) where the deposition rate may spike upwards. Thus, there may be a need to increase deposition in one area of the edge region while decreasing deposition in another area of the edge region to improve film thickness uniformity across the substrate.

The present technology overcomes these challenges by incorporating a faceplate that includes an annular protrusion and an annular groove at positions proximate the edge region of the substrate to help combat radial non-uniformity issues. For example, the protrusion may increase plasma density and deposition, while the groove may decrease plasma density and decrease the deposition rate. More specifically, the protrusion may reduce a distance between a surface of the faceplate and the substrate, which may increase the radical concentration (and in turn may increase deposition) and ion bombardment (which may reduce film thickness) of deposited film in the area of the substrate below the protrusion may be reduced. Conversely, the groove may increase a distance between a surface of the faceplate and the substrate and/or substrate support, which may decrease the radical concentration (and in turn may decrease deposition) and increase ion bombardment of deposited film in the area of the substrate below the protrusion. By positioning the groove radially outward of the protrusion, embodiments may be able to combat edge spikes at the very edge of the substrate while generally increasing the deposition at the remaining portion of the edge region.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

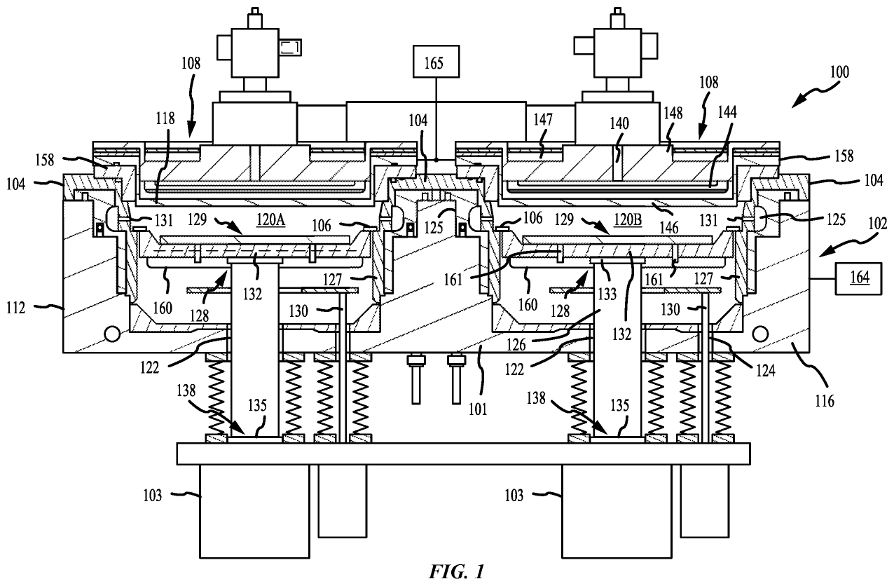

FIG. 1 shows a schematic cross-sectional view of an exemplary plasma enhanced processing system 100 according to some embodiments of the present technology. The plasma enhanced processing system 100 may illustrate a pair of processing chambers that may be fitted in one or more of tandem sections, and which may include substrate support assemblies according to embodiments of the present technology. The plasma enhanced processing system 100 generally may include a chamber body 102 having sidewalls 112, a bottom wall 116, and an interior sidewall 101 defining a pair of processing regions 120A and 120B. Each of the processing regions 120A-120B may be similarly configured and may include identical components.

For example, processing region 120B, the components of which may also be included in processing region 120A, may include a pedestal 128 disposed in the processing region through a passage 122 formed in the bottom wall 116 in the plasma enhanced processing system 100. The pedestal 128 may provide a heater adapted to support a substrate 129 on an exposed surface of the pedestal, such as a body portion. The pedestal 128 may include heating elements 132, for example resistive heating elements, which may heat and control the substrate temperature at a desired process temperature. Pedestal 128 may also be heated by a remote heating element, such as a lamp assembly, or any other heating device.

The body of pedestal 128 may be coupled by a flange 133 to a stem 126. The stem 126 may electrically couple the pedestal 128 with a power outlet or power box 103. The power box 103 may include a drive system that controls the elevation and movement of the pedestal 128 within the processing region 120B. The stem 126 may also include electrical power interfaces to provide electrical power to the pedestal 128. The power box 103 may also include interfaces for electrical power and temperature indicators, such as a thermocouple interface. The stem 126 may include a base assembly 138 adapted to detachably couple with the power box 103. A circumferential ring 135 is shown above the power box 103. In some embodiments, the circumferential ring 135 may be a shoulder adapted as a mechanical stop or land configured to provide a mechanical interface between the base assembly 138 and the upper surface of the power box 103.

A rod 130 may be included through a passage 124 formed in the bottom wall 116 of the processing region 120B and may be utilized to position substrate lift pins 161 disposed through the body of pedestal 128. The substrate lift pins 161 may selectively space the substrate 129 from the pedestal to facilitate exchange of the substrate 129 with a robot utilized for transferring the substrate 129 into and out of the processing region 120B through a substrate transfer port 260.

A chamber lid 104 may be coupled with a top portion of the chamber body 102. The lid 104 may accommodate one or more precursor distribution systems 108 coupled thereto. The precursor distribution system 108 may include a precursor inlet passage 140 which may deliver reactant and cleaning precursors through a showerhead 118 into the processing region 120B. The showerhead may include a single channel, or may include multiple channels (e.g., two, three, etc.). The showerhead 118 may include an annular base plate 148 having a blocker plate 144 disposed intermediate to a faceplate 146. A radio frequency (“RF”) source 165 may be coupled with the showerhead 118, which may power the showerhead 118 to facilitate generating a plasma region between the faceplate 146 of the showerhead 118 and the pedestal 128. In some embodiments, the RF source 165 may be coupled with the showerhead 118 directly or indirectly, such as via a strap or other connection extending between a gasbox and the showerhead 118. In some embodiments, the RF source may be coupled with other portions of the chamber body 102, such as the pedestal 128, to facilitate plasma generation. A dielectric isolator 158 may be disposed between the lid 104 and the dual-channel showerhead 118 to prevent conducting RF power to the lid 104. A shadow ring 106 may be disposed on the periphery of the pedestal 128 that engages the pedestal 128.

An optional cooling channel 147 may be formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 may be maintained at a predefined temperature. A liner assembly 127 may be disposed within the processing region 120B in close proximity to the sidewalls 101, 112 of the chamber body 102 to prevent exposure of the sidewalls 101, 112 to the processing environment within the processing region 120B. The liner assembly 127 may include a circumferential pumping cavity 125, which may be coupled to a pumping system 164 configured to exhaust gases and byproducts from the processing region 120B and control the pressure within the processing region 120B. A plurality of exhaust ports 131 may be formed on the liner assembly 127. The exhaust ports 131 may be configured to allow the flow of gases from the processing region 120B to the circumferential pumping cavity 125 in a manner that promotes processing within the system 100.

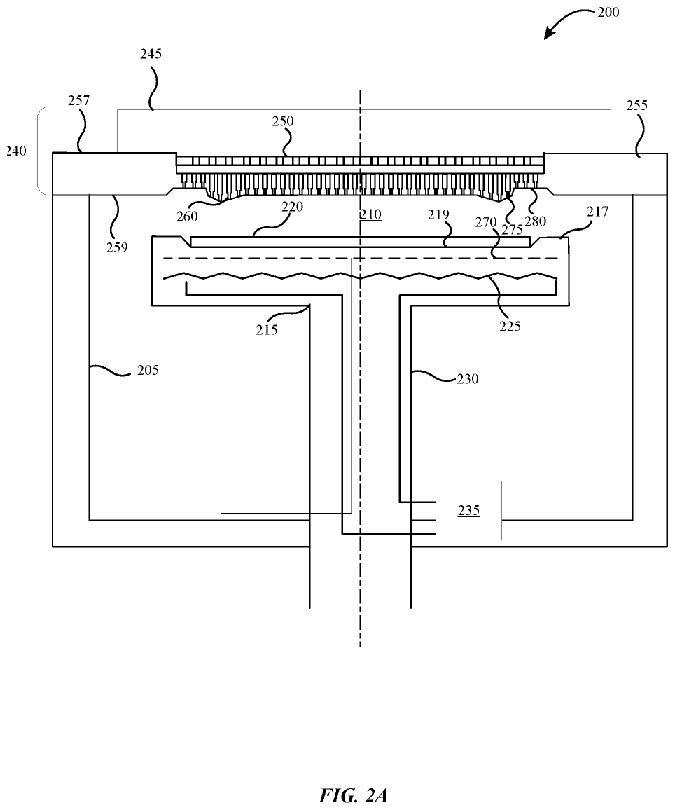

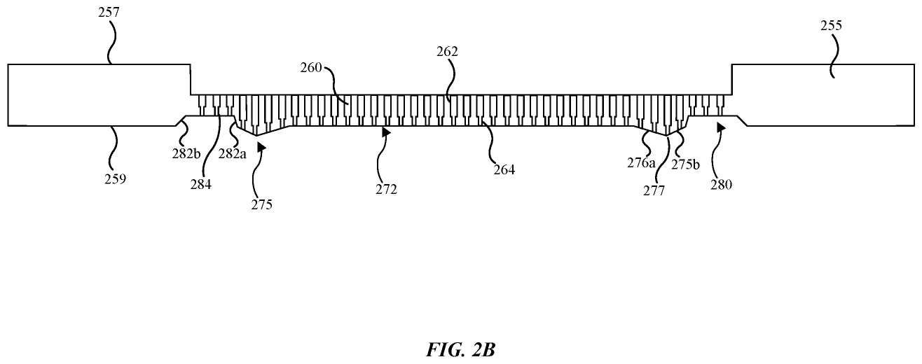

FIG. 2A shows a schematic cross-sectional view of a processing chamber 200 according to some embodiments of the present technology. FIG. 2A may include one or more components discussed above with regard to FIG. 1, and may illustrate further details relating to that chamber. The chamber 200 may be used to perform semiconductor processing operations including deposition of stacks of dielectric materials as previously described. Chamber 200 may show a partial view of a processing region of a semiconductor processing system, and may not include all of the components, such as additional lid stack components previously described, which are understood to be incorporated in some embodiments of chamber 200. The chamber 200 generally may include a chamber body 205 having sidewalls, a bottom wall, and an interior sidewall defining a processing region 210. Processing region 210 may include a substrate support 215 disposed in the processing region 210. The substrate support 215 may provide a heater adapted to support a substrate 220 on an exposed surface of the substrate support, such as a body portion. For example, the substrate support 215 may include a pocket 217 that defines an outer boundary of a substrate support surface 219. The pocket 217 may protrude upward from the substrate support 215, with a top surface of the pocket 217 being substantially aligned with a top surface of the substrate 220. For example, a top surface of the pocket 217 may be within or about 3% of a height of the top surface of the substrate 220, within or about 2% of the height of the top surface of the substrate 220, within or about 1% of the height of the top surface of the substrate 220, within or about 0.5% of the height of the top surface of the substrate 220, or less. For example, for a substrate 220 having a thickness of 1 mm, the height of the top surface of the pocket 217 may be between or about 0.970 mm and 1.030 mm, between or about 0.980 mm and 1.020 mm, between or about 0.990 mm and 1.010 mm, between or about 0.995 mm and 1.005 mm, or about 1 mm. The substrate support 215 may include heating elements 225, for example resistive heating elements, which may heat and control the substrate temperature at a desired process temperature. Substrate support 215 may also be heated by a remote heating element, such as a lamp assembly, or any other heating device.

The body of substrate support 215 may be to a stem 230. The stem 230 may electrically couple the substrate support 215 with a power outlet or power box 235. The power box 235 may include a drive system that controls the elevation and movement of the substrate support 215 within the processing region 210. The stem 230 may also include electrical power interfaces to provide electrical power to the substrate support 215. The power box 235 may also include interfaces for electrical power and temperature indicators, such as a thermocouple interface. A precursor distribution assembly 240 may be coupled with a top portion of the chamber body 205, possibly with one or more intervening components positioned therebetween. The precursor distribution assembly 240 may deliver reactant and cleaning precursors into the processing region 210. The precursor distribution assembly 240 may include a gasbox 245, a blocker plate 250, and/or a faceplate 255. In some embodiments, the faceplate 255 may be heated, such as to a temperature of between about 70° C. and 350° C. The gasbox 245 may define or provide access into a processing chamber. Blocker plate 250 may be positioned between the gasbox 245 and the substrate support 215. The blocker plate 250 may include or define a number of apertures through the plate. In some embodiments the blocker plate may be characterized by increased central conductance. For example, in some embodiments a subset of apertures proximate or extending about a central region of the blocker plate may be characterized by a greater aperture diameter than apertures radially outward of the central region. This may increase a central flow conductance in some embodiments. A radio frequency (“RF”) source (not shown) may be coupled with the gas distribution assembly 240, which may power the gas distribution assembly 240 to facilitate generating a plasma region between the faceplate 255 and the substrate support 215. In some embodiments, the RF source may be coupled with other portions of the chamber body 205, such as the substrate support 215, to facilitate plasma generation. For example, an RF mesh or electrode 270 may be embedded within a body of the substrate support 215 which may be supplied with RF power to facilitate generation of plasma within the processing region 210.

The faceplate 255 (which may be similar to and/or used as faceplate 146 and/or showerhead 118) may be positioned within the chamber 200 between the blocker plate 250 and the substrate support 215 as illustrated previously. Faceplate 255 may be characterized by a first surface 257 and a second surface 259, which may be opposite the first surface 257. In some embodiments, first surface 257 may be facing towards a blocker plate 250, and/or gasbox 245. Second surface 259 may be positioned to face substrate support 215 within the processing region 210 of chamber 200. For example, in some embodiments, the second surface 259 of the faceplate 255 and the substrate support 215 may at least partially define the processing region 210. Faceplate 255 may define a plurality of apertures 260 defined through the faceplate 255 and extending from the first surface 257 through the second surface 259. Each aperture 260 may provide a fluid path through the faceplate 255, and the apertures 260 may provide fluid access to the processing region of the chamber. Apertures 260 may have generally cylindrical cross-sections in some embodiments. As illustrated, each aperture 260 may have an aperture profile that includes a larger upper cylindrical portion 262 and a smaller lower cylindrical portion 264, although other aperture profiles are possible in various embodiments. The upper cylindrical portion 262 may have a greater diameter than the lower cylindrical portion 264. For example, the upper cylindrical portion 262 may have a diameter that is about 1.5× to 3× as big as a diameter of the lower cylindrical portion 264. In some embodiments, the upper cylindrical portion 262 may have a diameter of between or about 0.025 inch and 0.1 inch, between or about 0.030 inch and 0.095 inch, between or about 0.035 inch and 0.090 inch, between or about 0.040 inch and 0.085 inch, between or about 0.045 inch and 0.080 inch, between or about 0.050 inch and 0.075 inch, between or about 0.060 inch and 0.070 inch, or between or about 0.060 inch and 0.065 inch. The lower cylindrical portion 264 may have a diameter of between or about 0.0075 inch and 0.050 inch, between or about 0.010 inch and 0.045 inch, between or about 0.015 inch and 0.040 inch, between or about 0.020 inch and 0.035 inch, or between or about 0.025 inch and 0.030 inch. In some embodiments, a length of all or substantially all (e.g., a central hole may be different) of the lower cylindrical portions 264 may be the same or substantially the same to promote uniform gas flow conductance through the faceplate 255. For example, a length of the lower cylindrical portion 264 may be between or about 0.025 inch and 0.500 inch, between or about 0.050 inch and 0.250 inch, or between or about 0.075 inch and 0.100 inch. As will be discussed in greater detail below, a length of the upper cylindrical portion 262 may be adjusted from aperture 260 to aperture 260 to accommodate lower cylindrical portions 264 having a same length.

In some embodiments, a flow conductance through substantially all of the plurality of apertures may be substantially equal. For example, flow conductance may be driven by the relationship of D⁴/L, where D is a smallest diameter of a given aperture (e.g., lower cylindrical portion 264) and L is a length of such a portion of the aperture. All or substantially all (e.g., at least 90%, at least 95%, at least 99%, all but one aperture (e.g., a centermost aperture), or all apertures) may have an equal or substantially equal (e.g., within 10%, within 5%, within 3%, within 1%, or less) flow conductance across the surface of the faceplate 255.

Depending on the size of the faceplate 255, and the size of the apertures 260, faceplate 255 may define any number of apertures 260 through the plate, such as greater than or about 1,000 apertures, greater than or about 2,000 apertures, greater than or about 3,000 apertures, greater than or about 4,000 apertures, greater than or about 5,000 apertures, greater than or about 6,000 apertures, or more. As noted above, the apertures 260 may be included in a set of rings extending outward from a central axis of the faceplate 255, and may include any number of rings as described previously. The rings may be characterized by any number of shapes including circular or elliptical, as well as any other geometric pattern, such as rectangular, hexagonal, or any other geometric pattern that may include apertures distributed in a radially outward number of rings. The apertures may have a uniform or staggered spacing, and may be spaced apart at less than or about 10 mm from center to center. The apertures may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, apertures may be characterized by a scaling function of apertures per ring. For example, in some embodiments a first aperture may extend through a center of the faceplate, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number, as will be described further below where the first ring has an augmented number of apertures. For example, for an exemplary faceplate having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 50 rings. In some embodiments each aperture of the plurality of apertures across the faceplate may be characterized by an aperture profile, which may be the same or different in embodiments of the present technology.

As best illustrated in the partial schematic cross-sectional view of FIG. 2B, the second surface 259 (e.g., bottom surface facing the processing region) of the faceplate 255 may define an annular protrusion 275. The annular protrusion 275 may extend 360 degrees or less about the second surface 259. A cross-section of the annular protrusion 275 may be constant and/or vary along the circumference of the annular protrusion 275. The annular protrusion 275 may have any cross-sectional shape. For example, in some embodiments, the annular protrusion 275 may have a rectangular cross-sectional shape such that a height of the annular protrusion 275 is constant across a width of the annular protrusion 275 (e.g., parallel to first surface 257 of the faceplate 255). In other embodiments, the cross-section of the annular protrusion 275 may be tapered and/or contoured such that the height or depth of the annular protrusion 275 varies across the width of the annular protrusion 275 (e.g., the annular protrusion 275 is not parallel with a main surface 272 (e.g., inner region) of the second surface 259 of the faceplate 255). For example, as illustrated the annular protrusion 275 has a variable cross-section (e.g., a protrusion distance of the annular protrusion varies across all or part of a width of the annular protrusion 275), with two tapering sides 276 that meet at a peak 277. Each side 276 may taper at a same or different angle relative to the main surface 272 of the faceplate 255. As illustrated, an inner side 276a may have a lesser degree of taper than an outer side 276b, although other configurations are possible in various embodiments. The lesser degree of taper of the inner side 276a may result in the inner side 276a having a greater width (e.g., distance from an inner radial boundary to an outer radial boundary) than the outer side 276b. In some embodiments, the inner side 276a may make up between or about 10% and 90% of a width of the annular protrusion 275, between or about 20% and 80% of the length, between or about 30% and 70% of the length, between or about 40% and 60% of the length, or between or about 45% and 55% of the length, with the outer side 276b making up the remaining portion of the width. In some embodiments a total width of the annular protrusion 275 may be between or about 0.05 inch and 0.50 inch, between or about 0.1 inch and 0.40 inch, between or about 0.15 inch and 0.30 inch, or between or about 0.20 inch and 0.25 inch. In some embodiments, a vertical distance from the peak 277 to the main surface 272 may be between or about 0.005 inch and 0.2 inch, between or about 0.0075 inch and 0.1 inch, or between or about 0.001 inch and 0.05 inch, although larger annular protrusions 275 are possible in some embodiments to correct larger film thickness non-uniformity issues.

The annular protrusion 275 may be formed at a position of the faceplate 255 that is directly above an edge region of the substrate 220. For example, the annular protrusion 275 may be disposed directly above at least a portion of a radially outer 10% of the substrate support surface 219 and/or substrate 220, a radially outer 9%, a radially outer 8%, a radially outer 7%, a radially outer 6%, a radially outer 5%, a radially outer 4%, a radially outer 3%, a radially outer 2%, a radially outer 1%, or less. In some embodiments, an inner edge/boundary of the annular protrusion 275 may be located at a position that is within or about a radially outer 10% of the substrate support surface 219 and/or substrate 220, a radially outer 9%, a radially outer 8%, a radially outer 7%, a radially outer 6%, a radially outer 5%, a radially outer 4%, a radially outer 3%, a radially outer 2%, a radially outer 1%, or less. In some embodiments, an outer edge/boundary of the annular protrusion 275 may be located radially inward of a peripheral edge of the substrate 220 and/or substrate support surface 219. For example, the outer edge/boundary of the annular protrusion 275 may be located at a position that is inward of or about a radially outer 2% of the substrate support surface 219 and/or substrate 220, a radially outer 3%, a radially outer 4%, a radially outer 5%, a radially outer 6%, a radially outer 7%, or a radially outer 8%.

While not wishing to be bound to a particular theory, the annular protrusion 275 may reduce a distance between the second surface 259 of the faceplate 255 and the substrate 220 and/or substrate support surface 219, which may increase the oxygen radical concentration in the region of the substrate 220 beneath (and proximate) the annular protrusion 275. The increased oxygen radial concentration may lead to a greater plasma density and/or deposition rate within this region of the substrate 220 to combat areas of low film thickness. Additionally, the reduced distance between the second surface 259 of the faceplate 255 and the substrate 220 and/or substrate support surface 219 may help to reduce ion bombardment of deposited film in this region of the substrate 220. The reduction of ion bombardment may help protect the deposited film from being thinned by such ions and may help maintain the thicker layer of film deposition.

The second surface 259 of the faceplate 255 may also define an annular groove 280, which may be radially outward of the annular protrusion 275. The annular groove 280 may extend 360 degrees or less about the second surface 259. A cross-section of the annular groove 280 may be constant and/or vary along the circumference of the annular groove 280. The annular groove 280 may have any cross-sectional shape. For example, in some embodiments, the annular groove 280 may have a rectangular cross-sectional shape such that a depth of the annular groove 280 is constant across a width of the annular groove 280 (e.g., parallel to first surface 257 of the faceplate 255). In other embodiments, the cross-section of the annular groove 280 may be tapered and/or contoured such that the depth of the annular groove 280 varies across the width of the annular groove 280 (e.g., the annular groove 280 is not parallel with the main surface 272 of the second surface 259 of the faceplate 255). For example, the annular groove 280 may have a similar (but inverted) shape as the annular protrusion 275 in some embodiments, with two tapering sides that meet at a valley or trough of the annular groove 280. As illustrated, the annular groove 280 has a variable cross-section (e.g., a recessed distance of the annular groove 280 varies across a width of the annular groove 280), with two tapering walls or sides 282 that transition to a generally flat trough 284. Each side 282 may taper at a same or different angle relative to the main surface 272 of the faceplate 255. For example, each side 282 may have a degree of taper of between or about 10 degrees and 90 degrees relative to the main surface 272, between or about 15 degrees and 80 degrees, between or about 20 degrees and 70 degrees, between or about 25 degrees and 60 degrees, or between about 30 degrees and 50 degrees, although oftentimes being between or about 10 degrees and 45 degrees. As illustrated, an inner side 282a may have a greater degree of taper than an outer side 282b. For example, the inner side 282a may have a degree of taper of between or about 50 degrees and 90 degrees, while the outer side 282b may have a degree of taper of between or about 20 degrees and 50 degrees, although other configurations are possible. The greater degree of taper of the inner side 282a may result in the inner side 282a having a lesser width (e.g., distance from an inner radial boundary to an outer radial boundary) than the outer side 282b. In some embodiments, each side 282 may make up between or about 1% and 20% of a width of the annular groove 280, with the trough 284 making up the remaining portion of the width. In some embodiments, the trough 284 may be generally flat/planar with a constant or substantially constant depth as illustrated here. In other embodiments, the trough 284 may be curved and/or otherwise tapered, and may have one or more distinct high/low points.

In some embodiments a total width of the annular groove 280 may be between or about 0.1 inch and 1 inch, between or about 0.2 inch and 0.95 inch, between or about 0.3 inch and 0.9 inch, between or about 0.4 inch and 0.85 inch, between or about 0.5 inch and 0.8 inch, or between or about 0.6 inch and 0.75 inch, although other widths are possible in various embodiments. In some embodiments, a vertical distance (e.g., depth) of the annular groove 280 from the trough 284 to the main surface 272 may be between or about 0.001 inch and 0.05 inch, more commonly between or about 0.001 inch and 0.02 inch, between or about 0.0025 inch and 0.0175 inch, between or about 0.005 inch and 0.015 inch, between or about 0.0075 inch and 0.0125, or about 0.01 inch, although larger annular grooves 280 are possible in some embodiments to correct larger film thickness non-uniformity issues. In some embodiments, a vertical distance between the peak 277 of the annular protrusion 275 and the trough 284 of the annular groove 280 may be between or about 0.005 inch and 0.3 inch, more commonly between or about 0.005 inch and 0.2 inch, between or about 0.0075 inch and 0.15 inch, between or about 0.01 inch and 0.1 inch, between or about 0.0125 inch and 0.075 inch, or between or about 0.02 inch and 0.05 inch, although other vertical distances are possible in various embodiments. In some embodiments, a height of the annular protrusion 275 and a depth of the annular groove 280 may be the same, while in other embodiments the height of the annular protrusion 275 may be less than or greater than the depth of the annular groove 280.

The annular groove 280 may be formed at a position of the faceplate 255 that is radially outward of the annular groove 275 and that is directly above and/or radially outward of a portion of the edge region of the substrate 220 and/or the peripheral edge of the heater pocket 217. For example, an inner edge/portion of the annular groove 280 may be disposed directly above at least a portion of a radially outer 6%, a radially outer 5%, a radially outer 4%, a radially outer 3%, a radially outer 2%, a radially outer 1%, or less, while an outer edge/portion of the annular groove 280 may extend radially outward of the peripheral edge of the substrate 220 and/or the peripheral edge of the heater pocket 217. For example, an outer edge/boundary of the annular groove 280 may be located radially outward of a peripheral edge of the substrate 220, substrate support surface 219, and/or heater pocket 217 by at least or about 1% of a diameter of the substrate 220, substrate support surface 219, and/or heater pocket 217, by at least or about 2%, by at least or about 3%, by at least or about 4%, by at least or about 5%, by at least or about 6%, by at least or about 7%, by at least or about 8%, by at least or about 9%, by at least or about 10%, or more.

While not wishing to be bound to a particular theory, the annular groove 280 may increase a distance between the second surface 259 of the faceplate 255 and the substrate 220 and/or substrate support surface 219, which may decrease the radical concentration (e.g., O₂, O₃, N₂O, etc.) in the region of the substrate 220 beneath (and proximate) the annular groove 3280. The decreased oxygen radial concentration may lead to a lower plasma density and/or deposition rate within this region of the substrate 220 to combat areas of high film thickness. Additionally, the increased distance between the second surface 259 of the faceplate 255 and the substrate 220 and/or substrate support surface 219 may increase ion bombardment of deposited film in this region of the substrate 220. The increase of ion bombardment may reduce the thickness of the deposited film. Accordingly, the use of the annular groove 280 may help combat non-uniformity issues caused by the presence of the heater pocket 217. The presence of both the annular protrusion 275 and the annular groove 280 may help combat film thickness uniformity at the edge region of the substrate 220. In particular, by including the annular protrusion 275 and the annular groove 280 as described, non-uniformities that manifest as lower film thickness within the edge region as compared to the inner region, except at the very edge (e.g., outer 2%, etc.) of the substrate 220 where the deposition rate may spike upwards. For example, the presence of the annular protrusion 275 may increase the film thickness within the inner portion of the edge region, while the annular groove 280 may reduce the film thickness at the outer portion of the edge region. While illustrated with the annular groove 280 being radially outward of the annular protrusion 275, it will be appreciated that the relative positions may be reversed such that the annular groove 280 is radially inward of the annular protrusion 275 in some embodiments. This may be done to combat different types of film uniformity issues.

In some embodiments, to provide such improvements to film thickness uniformity, the annular protrusion 275 and annular groove 280 may be disposed proximate one another. For example, an outer edge of the annular protrusion 275 may be within about 10 mm of an inner edge of the annular groove 280, within or about 5 mm, within or about 3 mm, within or about 1 mm, or less. For example, a portion of main surface 272 may separate the outer side 276b and inner side 282a. In some embodiments, an outer edge of the annular protrusion 275 may be at a same radial position as an inner edge of the annular groove 280 such that the annular protrusion 275 and the annular groove 280 contact one another. For example, the outer side 276b may transition into inner side 282a (such as at a plane defining the main surface 272), with the outer side 276b and inner side 282a having a same or different angle relative to the main surface 272. For example, as illustrated, the inner side 282a has a steeper angle than the outer side 276b, although other configurations are possible in various embodiments.

In some embodiments, transitions between the various portions (e.g., main surface 272, annular protrusion 275, annular groove 280) of the second surface 259 of the faceplate 255 may include rounded corners. For example, the transitions may each have a radius of between or about 0.001 inch and 0.5 inch, between or about 0.005 inch and 0.04 inch, or between or about 0.01 inch and 0.3 inch. In some embodiments, concave radii may be smaller than convex radii. For example, the concave radii may be between or about 0.001 inch and 0.1 inch, between or about 0.0025 inch and 0.075, between or about 0.005 inch and 0.05 inch, between or about 0.00725 inch and 0.025 inch, or about 0.01 inch, although other concave radii are possible in various embodiments. The convex radii may be between or about 0.1 inch and 0.5 inch, between or about 0.15 inch and 0.45 inch, between or about 0.2 inch and 0.4 inch, between or about 0.25 inch and 0.35 inch, or about 0.3 inch, although other convex radii are possible in various embodiments. The use of rounded corners or transitions may help promote better flow uniformity within the processing region. Additionally, sharp corners may lead to charge concentrations, which may present a risk of arcing. Moreover, the use of sharp corners may cause film non-uniformity issues and/or create fall-on defects on the substrate 220.

The height and/or depth of the annular protrusion 275 and/or the annular groove 280 at a given locations may be selected to correspond with a desired change in the film thickness within the given area of the substrate 220. For example, if the film in an area of the substrate from about 90% of the diameter of the substrate 220 to about 98% of the radius of the substrate 220 is too thin, the annular protrusion 275 may be formed in the faceplate 255 above and/or slightly outward of this area to help decrease the film thickness in this area. Similarly, if the film in an area of the substrate from about 98% of the radius of the substrate 220 to about 100% of the diameter of the substrate 220 is too thick, the annular groove 280 may be formed in the faceplate 255 above and/or slightly outward of this area to help decrease the film thickness in this area.

As noted above, the faceplate 255 may define a number of apertures 260 through a thickness (e.g., from first surface 257 to second surface 259) of the faceplate 255. A first subset of the apertures 260 may be provided within the inner region of the faceplate 255, a second subset of the apertures 260 may extend through the annular protrusion 275, and a third subset (which may include a radially outermost aperture 260 or ring of apertures 260) may extend through the annular groove 280. To maintain uniform flow conductance across the faceplate 255, the lower portion 264 of each aperture 260 may be held constant. In some embodiments, the length of the lower portion 264 may be between or about 0.025 inch and 0.5 inch, between or about 0.05 inch and 0.4 inch, between or about 0.06 inch and 0.3 inch, between or about 0.07 inch and 0.2 inch, between or about 0.08 inch and 0.1 inch, or about 0.09 inch. For apertures 260 where the lowermost portion 264 extends through an angled portion of the annular protrusion 275 and/or annular groove 280, the length of the lower portion 264 may be measured from a top of the lower portion 264 (e.g., where the lower portion 264 and upper portion 262 meet) to a lowest portion where the lower portion 264 meets the second surface 259, a highest point where the lower portion 264 meets the second surface 259, an average length of the lower portion 264 based on a degree of taper of the annular protrusion 275 and/or annular groove 280, and/or other another technique. To achieve a constant length of lower portion 264, a length of the upper portion 262 may be varied across the apertures 260. For example, apertures 260 extending through the annular protrusion 275 may have longer upper portions 262 than apertures 260 extending through the main surface 272, while apertures 260 extending through the annular groove 280 may have shorter upper portions 262 than apertures 260 extending through the main surface 272.

While shown with the annular protrusion 275 and the annular groove 280 having linear sides/troughs, it will be appreciated that in some embodiments the annular protrusion 275 and/or annular groove 280 may include one or more contoured, curved, and/or otherwise non-linear sides, troughs, peaks, and/or other components. The shape of the annular protrusion 275 and/or annular groove 280 may be selected to provide an adjustment to deposition rate/film thickness to provide a more uniform film thickness across the entire surface of the substrate 220, and in particular at the edge region of the substrate 220. Additionally, the geometry of the faceplate 255 (e.g., size and/or location of the annular protrusion 275 and/or annular groove 280 may be selected based on a spacing between the faceplate 255 and the substrate seated atop substrate support 215.

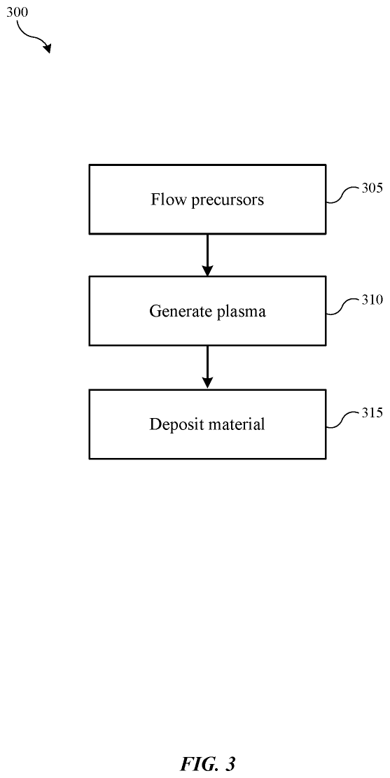

FIG. 3 shows operations of an exemplary method 300 of semiconductor processing according to some embodiments of the present technology. The method may be performed in a variety of processing chambers, including processing chamber 200 described above, which may include showerheads according to embodiments of the present technology, such as faceplate 255. Method 300 may include a number of optional operations, which may or may not be specifically associated with some embodiments of methods according to the present technology.

Method 300 may include a processing method that may include operations for forming a hardmask film or other deposition operations. The method may include optional operations prior to initiation of method 300, or the method may include additional operations. For example, method 300 may include operations performed in different orders than illustrated. In some embodiments, method 300 may include flowing one or more precursors into a processing chamber at operation 305. For example, the precursor may be flowed into a chamber, such as chamber 200, and may flow the precursor through one or more of a gasbox, a blocker plate, or a faceplate (such as faceplate 255), prior to delivering the precursor into a processing region of the chamber.

In some embodiments, the faceplate may define an annular protrusion that is disposed directly above at least a portion of a radially outer 10% of the substrate and an annular groove that is positioned radially outward of the annular protrusion. At least a portion of the annular groove may extend radially outward beyond the peripheral edge of the substrate. The faceplate may define a plurality of apertures through the faceplate, with a first subset of the plurality of apertures extending through the annular protrusion and a second subset of the plurality of apertures extending through the annular groove. At operation 310, a plasma may be generated of the precursors within the processing region, such as by providing RF power to the faceplate to generate a plasma. Material formed in the plasma may be deposited on the substrate at operation 315. In some embodiments, the deposited material may be characterized by a thickness at the edge of the substrate that approximately the same as a thickness within a central region of the substrate. For example, the material deposited is characterized by a thickness proximate an edge of the substrate has a target uniformity of less than 1500 A.

Additionally, the thickness at the edge of the substrate may be less than or about 9% greater than a thickness proximate a mid or center region along a radius of the substrate, and may be less than or about 8% greater, less than or about 7% greater, less than or about 6% greater, less than or about 5% greater, less than or about 4% greater, less than or about 3% greater, less than or about 2% greater, less than or about 1% greater, or may be substantially similar or uniform across positions along the substrate. By utilizing a faceplate having such an annular protrusion and groove combination, improved uniformity across the substrate may be provided.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a chamber body;
a substrate support disposed within the chamber body, the substrate support defining a substrate support surface; and
a faceplate supported atop the chamber body, wherein:
the substrate support and a bottom surface of the faceplate at least partially define a processing region within the semiconductor processing chamber;
the bottom surface of the faceplate defines an annular protrusion that is disposed directly above at least a portion of a radially outer 10% of the substrate support surface and an annular groove that is positioned radially outward of the annular protrusion, wherein at least a portion of the annular groove extends radially outward beyond the substrate support surface; and
the faceplate defines a plurality of apertures through the faceplate, wherein a first subset of the plurality of apertures extend through the annular protrusion and a second subset of the plurality of apertures extend through the annular groove.

2. The semiconductor processing chamber of claim 1, wherein:
the substrate support comprises a heater pocket that protrudes upward from an upper surface of the substrate support; and
the annular protrusion is disposed radially inward of a peripheral edge of the heater pocket.

3. The semiconductor processing chamber of claim 1, wherein:
an outer edge of the annular protrusion is at a same radial position as an inner edge of the annular groove.

4. The semiconductor processing chamber of claim 1, wherein:
a vertical distance between a peak of the annular protrusion and a valley of the annular groove is between about 0.05 inches and 0.3 inches.

5. The semiconductor processing chamber of claim 1, wherein:
transition areas between a main surface of the bottom surface of the faceplate one or both of the annular protrusion and the annular groove comprise rounded corners.

6. The semiconductor processing chamber of claim 1, wherein:
a width of one or both of the annular protrusion and the annular groove is between about 0.05 inches and 0.5 inches.

7. The semiconductor processing chamber of claim 3, wherein:
the annular protrusion protrudes from a main surface of the bottom surface of the faceplate by a distance of between about 0.005 inches and 0.2 inches.

8. The semiconductor processing chamber of claim 1, wherein:
the annular groove is recessed relative to a main surface of the bottom surface of the faceplate by a distance of between about 0.001 inches and 0.05 inches.

9. The semiconductor processing chamber of claim 1, wherein:
walls defining the annular groove extend at an angle of between about 10 degrees and 45 degrees relative to a main surface of the bottom surface of the faceplate.

10. A semiconductor processing faceplate, comprising:
a body defining a top surface and a bottom surface of the faceplate, wherein:
the bottom surface of the faceplate defines an annular protrusion and an annular groove that is positioned radially outward of the annular protrusion;
an outer edge of the annular protrusion is within 5 mm of an inner edge of the annular groove;
the faceplate defines a plurality of apertures through the faceplate, wherein a first subset of the plurality of apertures extend through the annular protrusion and a second subset of the plurality of apertures extend through the annular groove; and
an outermost aperture of the plurality of apertures extends through the annular groove.

11. The semiconductor processing faceplate of claim 10, wherein:
a transition area between the annular protrusion and the annular groove comprises rounded corners.

12. The semiconductor processing faceplate of claim 10, wherein:
each of the plurality of apertures comprises an upper cylindrical portion and a lower cylindrical portion, the lower cylindrical portion having a smaller diameter than the upper cylindrical portion.

13. The semiconductor processing faceplate of claim 12, wherein:
the lower cylindrical portion of each of the plurality of apertures has a same length and diameter.

14. The semiconductor processing faceplate of claim 13, wherein:
a flow conductance through substantially all of the plurality of apertures is substantially equal.

15. The semiconductor processing faceplate of claim 10, wherein:
a protrusion distance of the annular protrusion varies across a width of the annular protrusion.

16. The semiconductor processing faceplate of claim 10, wherein:
a distance from a trough of the annular groove and a main surface of the bottom surface of the faceplate is greater than or equal to a distance from a peak of the annular protrusion and the main surface.

17. The semiconductor processing faceplate of claim 10, wherein:
the annular protrusion is not parallel with a main surface of the bottom surface of the faceplate.

18. A method of processing a substrate, comprising:
flowing a precursor into a processing chamber, wherein:
the processing chamber comprises a faceplate and a substrate support on which a substrate is disposed;
a processing region of the processing chamber is at least partially defined between the faceplate and the substrate support;
a bottom surface of the faceplate defines an annular protrusion that is disposed directly above at least a portion of a radially outer 10% of the substrate and an annular groove that is positioned radially outward of the annular protrusion, wherein at least a portion of the annular groove extends radially outward beyond the substrate;
the faceplate defines a plurality of apertures through the faceplate, wherein a first subset of the plurality of apertures extend through the annular protrusion and a second subset of the plurality of apertures extend through the annular groove;
generating a plasma of the precursor within a processing region of the processing chamber; and
depositing a material on the substrate.

19. The method of processing a substrate of claim 18, wherein:
the annular protrusion and the annular groove contact one another.

20. The method of processing a substrate of claim 18, wherein:
a vertical distance between a peak of the annular protrusion and a valley of the annular groove is between about 0.05 inches and 0.3 inches.
